(19) United States
(12) Patent Application Publication
(10) Pub. No.: US 2019/0225744 A1
(43) Pub. Date: Jul. 25, 2019

(54) ACTIVE ESTER RESIN COMPOSITION AND CURED PRODUCT OF SAME

(71) Applicant: DIC Corporation, Tokyo (JP)

(72) Inventors: Akito Kawasaki, Ichihara-shi (JP); Yutaka Satou, Ichihara-shi (JP); Tatsuya Okamoto, Ichihara-shi (JP)

(21) Appl. No.: 16/313,310

(22) PCT Filed: Jun. 22, 2017
(86) PCT No.: PCT/JP2017/022997

§ 371 Date: Dec. 26, 2018

(30) Foreign Application Priority Data
Jul. 6, 2016 (JP) 2016-134227
Jul. 15, 2016 (JP) 2016-140420

(51) Int. Cl. C08G 63/42; C08G 63/78; H01L 23/29; H05K 1/03

(52) U.S. Cl. CPC C08G 63/42; C08G 63/78; H01L 23/295; H05K 1/0353; H01L 23/293

(57) ABSTRACT

Provided are an active ester resin composition capable of both exhibiting low shrinkage during curing and forming a cured product having a low elastic modulus under high temperature conditions; a curable resin composition including the ester resin composition; a cured product of the curable resin composition; a printed wiring board; and a semiconductor encapsulating material. The active ester resin composition includes an active ester compound (A) that is an esterification product of a naphthol compound (a1) and an aromatic polycarboxylic acid or an acid halide thereof (a2); and an active ester resin (B) including a product of reaction of essential raw materials including a compound (b1) having one phenolic hydroxyl group, a compound (b2) having two or more phenolic hydroxy groups, and an aromatic polycarboxylic acid or an acid halide thereof (b3), in which the content of the active ester compound (A) is 40% or more.

### TECHNICAL FIELD

The present invention relates to an active ester resin composition capable of exhibiting low shrinkage during curing and capable of forming a cured product having a low elastic modulus under high temperature conditions, a curable resin composition including this active ester resin composition, a cured product of the curable resin composition, a semiconductor encapsulating material, and a printed wiring board.

### BACKGROUND ART

In the technical field for insulating materials that are used for semiconductors, multilayer printed substrates, and the like, along with the thickness reduction or size reduction of various electronic members, there is a demand for the development of new resin materials in accordance with these market trends. Regarding the performance required from semiconductor encapsulating materials, a low elastic modulus upon heating is required for an enhancement of reflow characteristics. Furthermore, a decrease in reliability has become noticeable due to the “warpage” of members caused by thickness reduction of semiconductors in recent years, and in order to suppress this, there is a demand for the development of resin materials having low cure shrinkage.

A resin material capable of forming a cured product having a low elastic modulus during heating includes an active ester resin obtained by esterifying a dicyclopentadiene phenol resin and α-naphthol with phthalic acid chloride (see PTL 1 listed below). The active ester resin described in PTL 1 will provide a low crosslinking density as compared with the case of using a curing agent of a conventional type such as a phenol novolac resin, and thus exhibits low elastic modulus properties during heating. However, it does not meet the level required in recent years, and has high melt viscosity. Thus, it is not suitable for use in semiconductor encapsulating materials. Furthermore, it also has high cure shrinkage properties.

### CITATION LIST

### Patent Literature

PTL 1: JP-A-2004-169021

### SUMMARY OF INVENTION

### Technical Problem

Therefore, an object to be solved by the present invention is to provide an active ester resin capable of both exhibiting low shrinkage during curing and forming a cured product having a low elastic modulus under high temperature conditions; a curable resin composition including the ester resin composition; a cured product of the curable resin composition; a semiconductor encapsulating material; and a printed wiring board.

### Solution to Problem

The inventors have conducted a thorough investigation in order to solve the problems described above, and as a result, the inventors have found that an active ester resin composition including, as a component, an active ester compound that is an esterification product of a naphthol compound (a1) and an aromatic polycarboxylic acid or an acid halide thereof (a2) can form a cured product having a low elastic modulus under high temperature conditions and also has low shrinkage during curing. Thus, the inventors have completed the invention.

Specifically, the present invention relates to an active ester resin composition including: an active ester compound (A) that is an esterification product of a naphthol compound (a1) and an aromatic polycarboxylic acid or an acid halide thereof (a2); and an active ester resin (B) including a product of reaction of essential raw materials including a compound (b1) having one phenolic hydroxyl group, a compound (b2) having two or more phenolic hydroxyl groups, and an aromatic polycarboxylic acid or an acid halide thereof (b3), in which the content of the active ester compound (A) is 40% or more based on the total amount of the active ester compound (A) and the active ester resin (B).

The invention further relates to a curable resin composition including the above active ester resin composition and a curing agent.

The invention further relates to a cured product of the above curable resin composition.

The invention further relates to a semiconductor encapsulating material produced using the above curable resin composition.

The invention further relates to a printed wiring board produced using the above curable composition.

### Advantageous Effects of Invention

The invention makes it possible to provide an active ester resin composition capable of both exhibiting low shrinkage during curing and forming a cured product having a low elastic modulus under high temperature conditions; a curable resin composition including the ester resin composition; a cured product of the curable resin composition; a semiconductor encapsulating material; and a printed wiring board.

### BRIEF DESCRIPTION OF DRAWINGS

FIG. 1 is a GPC chart of active ester resin composition (1) obtained in Example 1.

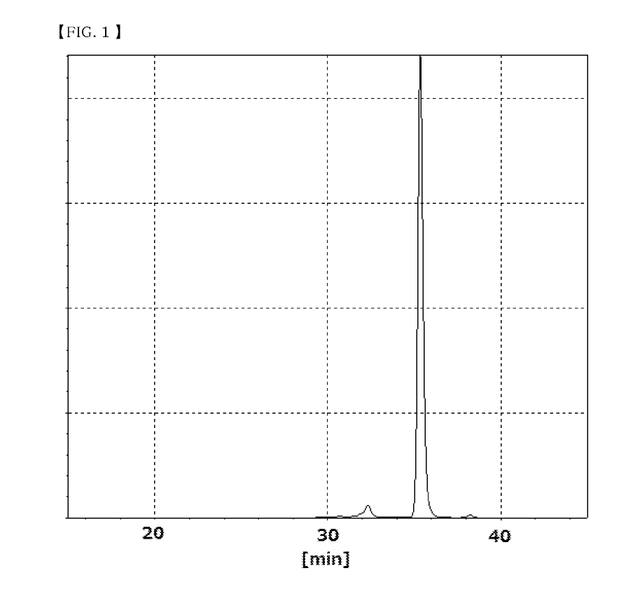

FIG. 2 is a GPC chart of active ester resin composition (2) obtained in Example 2.

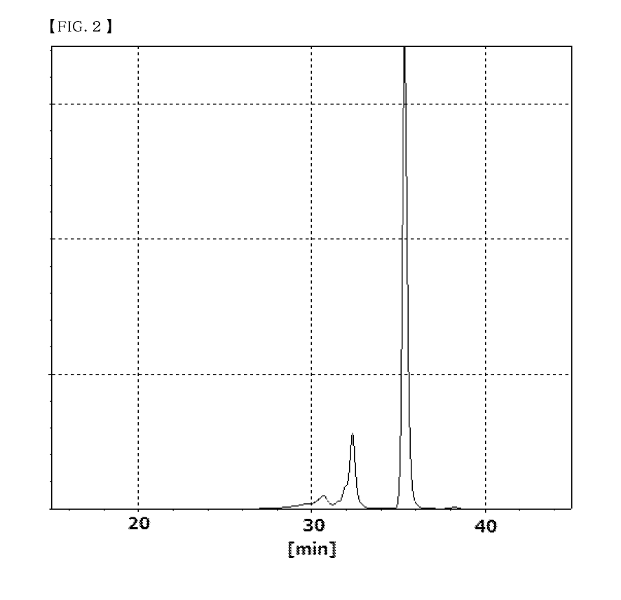

### DESCRIPTION OF EMBODIMENTS

Hereinafter, the invention will be described in detail.

An active ester resin composition according to the invention includes an active ester compound (A) that is an esterification product of a naphthol compound (a1) and an aromatic polycarboxylic acid or an acid halide thereof (a2); and an active ester resin (B) including a product of reaction of essential raw materials including a compound (b1) having one phenolic hydroxyl group, a compound (b2) having two or more phenolic hydroxyl groups, and an aromatic polycarboxylic acid or an acid halide (b3), in which the content of the active ester compound (A) is 40% or more based on the total amount of the active ester compound (A) and the active ester resin (B).

The content of the active ester compound (A) based on the total amount of the active ester compound (A) and the active ester resin (B) is a value calculated from the area ratio of a GPC chart measured under the following conditions. In particular, to form an active ester resin composition capable of both exhibiting low shrinkage during curing and forming a cured product having an elastic modulus under high temperature conditions, the content of the active ester compound (A) is preferably in the range of 40% to 99%, more preferably in the range of 50% to 99%, and particularly preferably in the range of 65% to 99%.

Measuring apparatus: “HLC-8320 GPC” manufactured by Tosoh Corporation

Column: Guide column “HXL-L” manufactured by Tosoh Corporation
“TSK-GEL G2000HXL” manufactured by Tosoh Corporation
“TSK-GEL G2000HXL” manufactured by Tosoh Corporation
“TSK-GEL G3000HXL” manufactured by Tosoh Corporation
“TSK-GEL G4000HXL” manufactured by Tosoh Corporation
   Detector: RI (differential refractometer)
   Data processing: “GPC Workstation EcoSEC-WorkStation” manufactured by Tosoh Corporation
   Measurement conditions: Column temperature 40° C.
Developing solvent tetrahydrofuran
Flow rate 1.0 ml/min
   Standards: The following monodisperse polystyrenes having known molecular weights were used according to the measurement manual of “GPC Workstation EcoSEC-WorkStation”.

(Polystyrenes Used)
“A-500” manufactured by Tosoh Corporation
“A-1000” manufactured by Tosoh Corporation
“A-2500” manufactured by Tosoh Corporation
“A-5000” manufactured by Tosoh Corporation
“F-1” manufactured by Tosoh Corporation
“F-2” manufactured by Tosoh Corporation
“F-4” manufactured by Tosoh Corporation
“F-10” manufactured by Tosoh Corporation
“F-20” manufactured by Tosoh Corporation
“F-40” manufactured by Tosoh Corporation
“F-80” manufactured by Tosoh Corporation
“F-128” manufactured by Tosoh Corporation
   Sample: A tetrahydrofuran solution having a concentration of 1.0% by mass in terms of the resin solid content was filtered through a microfilter (50 μl) and used.

Regarding the active ester compound (A), the specific structure of the compound is not particularly limited as long as the compound is an esterification product of a naphthol compound (a1) and an aromatic polycarboxylic acid or an acid halide thereof (a2). That is, regarding the naphthol compound (a1), as long as the naphthol compound is a compound having one hydroxyl group on the naphthalene ring, the presence or absence of other substituents, the number of substituents, the type of the substituent, the position of substitution, and the like do not matter. Meanwhile, regarding the aromatic polycarboxylic acid or an acid halide thereof (a2), as long as the compound is a compound having a plurality of carboxyl groups or acid halide groups on the aromatic ring, the number and the position of substitution of carboxyl groups or acid halide groups may be arbitrary, and the aromatic ring may be any one of a benzene ring, a naphthalene ring, an anthracene ring, and the like. Furthermore, in this invention, one kind of the active ester compound (A) may be used alone, or two or more kinds thereof may be used in combination.

The specific structure of the active ester compound (A) may be, for example, a structure represented by the following structural formula (1):

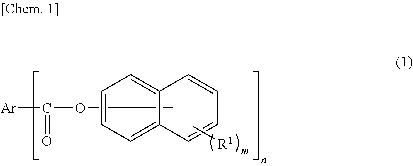

wherein Ar represents any one of a benzene ring, a naphthalene ring, and an anthracene ring; R¹'s each independently represent any one of an aliphatic hydrocarbon group, an alkoxy group, a halogen atom, an aryl group, and an aralkyl group; m represents 0 or an integer of 1 to 4; and n represents an integer of 2 or 3.

Ar in structural formula (1) is any one of a benzene ring, a naphthalene ring, and an anthracene ring. Among them, from the viewpoint that the viscosity of the active ester compound (A) is further decreased, a benzene ring or a naphthalene ring is preferred, and a benzene ring is particularly preferred. Furthermore, from the viewpoint of obtaining an active ester compound (A) having high curability, it is particularly preferable that n in structural formula (1) is 2. In a case in which Ar is a benzene ring, and n is 2, the positions of two ester bonds on the benzene ring are preferably the 1- and 3-positions or the 1- and 4-positions. That is, it is preferable to use isophthalic acid or terephthalic acid as the aromatic polycarboxylic acid or an acid halide thereof (a2).

R¹'s in structural formula (1) each independently represent any one of an aliphatic hydrocarbon group, an alkoxy group, a halogen atom, an aryl group, and an aralkyl group, and m represents 0 or an integer of 1 to 4. Specific examples of R¹ include aliphatic hydrocarbon groups such as a methyl group, an ethyl group, a vinyl group, a propyl group, a butyl group, a pentyl group, a hexyl group, a cyclohexyl group, a heptyl group, an octyl group, and a nonyl group; alkoxy groups such as a methoxy group, an ethoxy group, a propyloxy group, and a butoxy group; halogen atoms such as a fluorine atom, a chlorine atom, and a bromine atom; a phenyl group, a naphthyl group, an anthryl group, and aryl groups substituted with the above-mentioned aliphatic hydrocarbon groups, alkoxy groups, halogen atoms, and the like on these aromatic nuclei; a phenylmethyl group, a phenylethyl group, a naphthylmethyl group, a naphthylethyl group, and aralkyl groups substituted with the above-mentioned aliphatic hydrocarbon groups, alkoxy groups, halogen atoms, and the like on these aromatic nuclei. Among them, from the viewpoint of obtaining an active ester resin composition that has low shrinkage upon curing and gives a cured product having a low elastic modulus under high temperature conditions, m is preferably 0. Furthermore, the position of an ester bond on the naphthalene ring in structural formula (1) may be any of the 1-position and the 2-position. That is, regarding the naphthol compound (a1), it is preferable to use 1-naphthol or 2-naphthol.

The reaction between the naphthol compound (a1) and the aromatic polycarboxylic acid or an acid halide thereof (a2) can be carried out by, for example, a method of heating and stirring the compounds in the presence of an alkali catalyst under the temperature conditions of about 40° C. to 65° C. The reaction may also be carried out in an organic solvent as necessary. Furthermore, after completion of the reaction, if desired, the reaction product may be purified by washing with water, reprecipitation, or the like.

Examples of the alkali catalyst include sodium hydroxide, potassium hydroxide, triethylamine, and pyridine. These may be used singly, or two or more kinds thereof may be used in combination. Furthermore, the alkali catalyst may be used as an aqueous solution at about 3.0% to 30%. Above all, sodium hydroxide or potassium hydroxide, both of which have high catalytic activity, is preferred.

Examples of the organic solvent include ketone solvents such as acetone, methyl ethyl ketone, and cyclohexanone; acetic acid ester solvents such as ethyl acetate, butyl acetate, cellosolve acetate, propylene glycol monomethyl ether acetate, and carbitol acetate; carbitol solvents such as cellosolve and butyl carbitol; aromatic hydrocarbon solvents such as toluene and xylene; dimethylformamide, dimethylacetamide, and N-methylpyrrolidone. These may be respectively used singly, or may be used as mixed solvents of two or more kinds thereof.

Regarding the reaction proportions of the naphthol compound (a1) and the aromatic polycarboxylic acid or an acid halide thereof (a2), from the viewpoint of obtaining a desired active ester compound (A) with high yield, it is preferable that the proportion of the naphthol compound (a1) is 0.95 to 1.05 mol with respect to 1 mol of the total amount of carboxyl groups or acid halide groups carried by the aromatic polycarboxylic acid or an acid halide thereof (a2).

The active ester resin (B) is a product of reaction of essential raw materials including a compound (b1) having one phenolic hydroxyl group, a compound (b2) having two or more phenolic hydroxyl groups, and an aromatic polycarboxylic acid or an acid halide thereof (b3).

The compound (b1) having one phenolic hydroxyl group may be any compound as long as it is an aromatic compound having one hydroxyl group on the aromatic ring, and there are no particular limitations on other specific structures thereof. Furthermore, regarding the compound (b1) having one phenolic hydroxyl group, one kind thereof may be used alone, or two or more kinds thereof may be used in combination. Specific examples of the compound (b1) having one phenolic hydroxyl group include phenol, naphthol, anthracenol, and compounds having one substituent or a plurality of substituents on these aromatic nuclei. Examples of the substituent on the aromatic nuclei include aliphatic hydrocarbon groups such as a methyl group, an ethyl group, a vinyl group, a propyl group, a butyl group, a pentyl group, a hexyl group, a cyclohexyl group, a heptyl group, an octyl group, and a nonyl group; alkoxy groups such as a methoxy group, an ethoxy group, a propyloxy group, and a butoxy group; halogen atoms such as a fluorine atom, a chlorine atom, and a bromine atom; a phenyl group, a naphthyl group, an anthryl group, and aryl groups substituted with the above-mentioned aliphatic hydrocarbon groups, alkoxy groups, halogen atoms, and the like on these aromatic nuclei; a phenylmethyl group, a phenylethyl group, a naphthylmethyl group, a naphthylethyl group, and aralkyl groups substituted with the above-mentioned aliphatic hydrocarbon groups, alkoxy groups, halogen atoms, and the like on these aromatic nuclei. Among these, from the viewpoint of obtaining an active ester resin composition that has low shrinkage upon curing and gives a cured product having a low elastic modulus under high temperature conditions, a naphthol compound is preferred, and 1-naphthol or 2-naphthol is particularly preferred.

The compound (b2) having two or more phenolic hydroxyl groups may be any compound as long as the compound is a compound that has two or more hydroxyl groups in the molecular structure and is substituted with those hydroxyl groups on the aromatic ring, and there are no particular limitations on other specific structures thereof. Furthermore, regarding the compound (b2) having two or more phenolic hydroxyl groups, one kind thereof may be used alone, or two or more kinds thereof may be used in combination. Specific examples of the compound (b2) having two or more phenolic hydroxyl groups include polyhydroxybenzene, polyhydroxynaphthalene, polyhydroxyanthracene, and compounds having one substituent or a plurality of substituents on these aromatic nuclei. In addition to these, examples also include various novolac type phenol resins having various phenolic hydroxyl group-containing compounds and formaldehyde as reaction raw materials, and a compound having a molecular structure represented by the following structural formula (2):

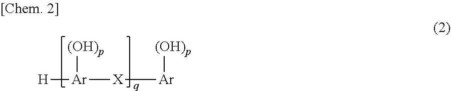

wherein p represents 1 or 2; q represents an integer of 1 to 4; Ar represents an aromatic ring and may have one substituent or a plurality of various substituents on the aromatic ring; and X represents a structural moiety linking aromatic rings each represented by Ar.

In regard to the above-mentioned various novolac type resins, examples of the phenolic hydroxyl group-containing compound that serves as a raw material include phenol, naphthol, anthracenol, dihydroxybenzene, dihydroxynaphthalene, and dihydroxyanthracene, as well as compound shaving one substituent or a plurality of substituents on these aromatic nuclei. Examples of the substituent on the aromatic ring include aliphatic hydrocarbon groups such as a methyl group, an ethyl group, a vinyl group, a propyl group, a butyl group, a pentyl group, a hexyl group, a cyclohexyl group, a heptyl group, an octyl group, and a nonyl group; alkoxy groups such as a methoxy group, an ethoxy group, a propyloxy group, and a butoxy group; halogen atoms such as a fluorine atom, a chlorine atom, and a bromine atom; a phenyl group, a naphthyl group, an anthryl group, and aryl groups substituted with the above-mentioned aliphatic hydrocarbon group, alkoxy group, halogen atom, and the like on these aromatic nuclei; a phenylmethyl group, a phenylethyl group, a naphthylmethyl group, a naphthylethyl group, and aralkyl groups substituted with the above-mentioned aliphatic hydrocarbon group, alkoxy group, halogen atom, and the like on these aromatic nuclei. Among these, from the viewpoint of obtaining an active ester resin composition that has low shrinkage upon curing and gives a cured product having a low elastic modulus under high temperature conditions, naphthol, dihydroxynaphthalene, and compounds having one substituent or a plurality of substituents on these aromatic nuclei are preferred, and naphthol is preferred. The naphthol may be any of 1-naphthol and 2-naphthol.

The novolac type resin can be produced by a method similar to a general method for a phenolic resin. Specifically, the novolac type resin can be produced by a method of heating and stirring the raw materials under acid catalyst conditions and under the temperature conditions of about 80° C. to 180° C.

Examples of the acid catalyst include inorganic acids such as hydrochloric acid, sulfuric acid, and phosphoric acid; organic acids such as methanesulfonic acid, para-toluenesulfonic acid, and oxalic acid; and Lewis acids such as boron trifluoride, anhydrous aluminum chloride, and zinc chloride. These may be used singly, or two or more kinds thereof may be used in combination. The amount of use of these acid catalysts is preferably in the range of 0.1% to 5% by mass with respect to the total mass of the reaction raw materials.

The reaction proportions of the phenolic hydroxyl group-containing compound and formaldehyde are appropriately adjusted according to the desired performance and the like for the active ester resin composition; however, for example, it is preferable to use formaldehyde in an amount in the range of 0.01 to 0.9 mol, and more preferably in the range of 0.1 to 0.5 mol, with respect to 1 mol of the phenolic hydroxyl group-containing compound. Formaldehyde may be used as a formalin solution, or may be used as para-formaldehyde.

The reaction may be carried out in an organic solvent as necessary, and examples of the organic solvent include ketone solvents such as acetone, methyl ethyl ketone, and cyclohexanone; acetic acid ester solvents such as ethyl acetate, butyl acetate, cellosolve acetate, propylene glycol monomethyl ether acetate, and carbitol acetate; carbitol solvents such as cellosolve and butyl carbitol; aromatic hydrocarbon solvents such as toluene and xylene; dimethylformamide, dimethylacetamide, and N-methylpyrrolidone. These may be used singly, or may be used as mixed solvents of two or more kinds thereof.

After completion of the reaction, any excess amount of unreacted raw materials may be distilled off or the like, if desired. Furthermore, the reaction mixture may be subjected to a neutralization treatment and then purified by washing with water, reprecipitation, or the like.

The hydroxyl group equivalent of the novolac type resin is preferably in the range of 120 to 250 g/equivalent.

In regard to the compound having a molecular structure represented by structural formula (2) described above, examples of the aromatic ring represented by Ar include a benzene ring, a naphthalene ring, an anthracene ring, and compounds having one substituent or a plurality of substituents on these aromatic rings. Examples of the substituent on the aromatic ring include aliphatic hydrocarbon groups such as a methyl group, an ethyl group, a vinyl group, a propyl group, a butyl group, a pentyl group, a hexyl group, a cyclohexyl group, a heptyl group, an octyl group, and a nonyl group; alkoxy groups such as a methoxy group, an ethoxy group, a propyloxy group, and a butoxy group; halogen atoms such as a fluorine atom, a chlorine atom, and a bromine atom; a phenyl group, a naphthyl group, an anthryl group, and aryl groups substituted with the above-mentioned aliphatic hydrocarbon group, alkoxy group, halogen atom, and the like on these aromatic nuclei; a phenylmethyl group, a phenylethyl group, a naphthylmethyl group, a naphthylethyl group, and aralkyl groups substituted with the above-mentioned aliphatic hydrocarbon group, alkoxy group, halogen atom, and the like on these aromatic nuclei. Among these, from the viewpoint of obtaining an active ester resin composition that has low shrinkage upon curing and gives a cured product having a low elastic modulus under high temperature conditions, Ar is preferably a naphthalene ring. Furthermore, p in structural formula (2) is preferably 1, and in a case in which Ar is a naphthalene ring, the position of substitution of the hydroxyl group on the naphthalene ring may be any of the 1-position and the 2-position.

In regard to structural formula (2), in a case in which Ar is a naphthalene ring, and p is 1, the compound having a molecular structure represented by structural formula (2) is more specifically a compound having a molecular structure represented by the following structural formula (2-1):

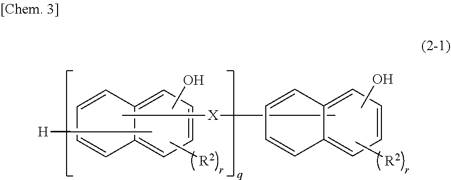

wherein X represents a structural moiety linking naphthalene rings; R²'s each independently represent any one of an aliphatic hydrocarbon group, an alkoxy group, a halogen atom, an aryl group, an aralkyl group, and a bonding point connected to a structural moiety represented by the following structural formula (3) via X:

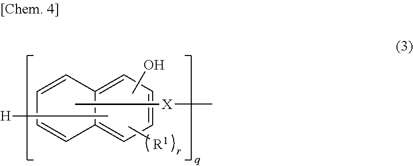

wherein X represents an aromatic nucleus- or cyclo ring-containing structural moiety; R²'s each independently represent any one of an aliphatic hydrocarbon group, an alkoxy group, a halogen atom, an aryl group, an aralkyl group, and a bonding point connected to a structural moiety represented by structural formula (3) via X, and each R² may be bonded to any carbon atom forming the naphthalene ring; r represents 0 or an integer of 1 to 4; and q represents an integer of 1 to 4,

each R² may be bonded to any carbon atom forming a naphthalene; r represents 0 or an integer of 1 to 4; and q represents an integer of 1 to 4.

X in structural formula (2) is a structural moiety linking aromatic rings represented by Ar, and the specific structure is not particularly limited. Examples include various groups such as an aliphatic hydrocarbon group other than a methylene group, and an aromatic ring- or cyclo ring-containing structural moiety. Specific examples include an alkylene group such as an ethylene group, a propylene group, a dimethylmethylene group, a propylmethylene group, or a t-butylmethylene group; and a structural moiety represented by any one of the following structural formulas (X-1) to (X-5):

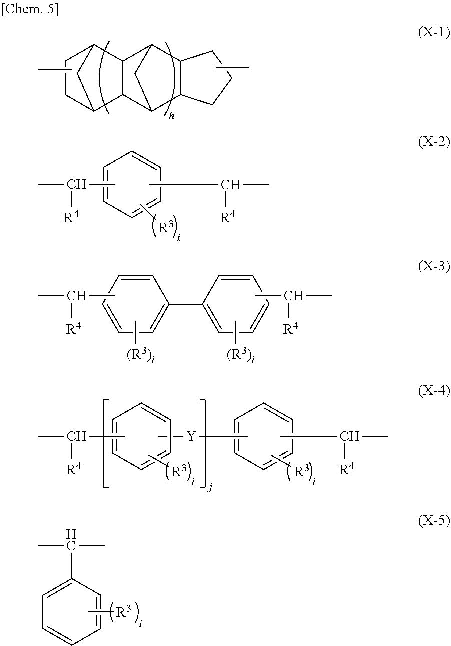

wherein h represents 0 or 1; R³'s each independently represent any one of an aliphatic hydrocarbon group, an alkoxy group, a halogen atom, an aryl group, and an aralkyl group; i represents 0 or an integer of 1 to 4; R⁴ represents a hydrogen atom or a methyl group; Y represents any one of an alkylene group having 1 to 4 carbon atoms, an oxygen atom, a sulfur atom, and a carbonyl group; and j represents an integer of 1 to 4.

R³'s in structural formulas (X-1) to (X-5) described above each independently represent any one of an aliphatic hydrocarbon group, an alkoxy group, a halogen atom, an aryl group, and an aralkyl group, and specific examples include aliphatic hydrocarbon groups such as a methyl group, an ethyl group, a vinyl group, a propyl group, a butyl group, a pentyl group, a hexyl group, a cyclohexyl group, a heptyl group, an octyl group, and a nonyl group; alkoxy groups such as a methoxy group, an ethoxy group, a propyloxy group, and a butoxy group; halogen atoms such as a fluorine atom, a chlorine atom, and a bromine atom; a phenyl group, a naphthyl group, an anthryl group, and aryl groups substituted with the above-mentioned aliphatic hydrocarbon group, alkoxy group, halogen atom, and the like on these aromatic nuclei; a phenylmethyl group, a phenylethyl group, a naphthylmethyl group, a naphthylethyl group, and aralkyl groups substituted with the above-mentioned aliphatic hydrocarbon group, alkoxy group, halogen atom, and the like on these aromatic nuclei.

The compound represented by structural formula (2) can be produced by, for example, a method of heating and stirring an aromatic hydroxy compound corresponding to Ar in structural formula (2) and a compound (x) represented by any one of the following structural formulas (x-1) to (x-5):

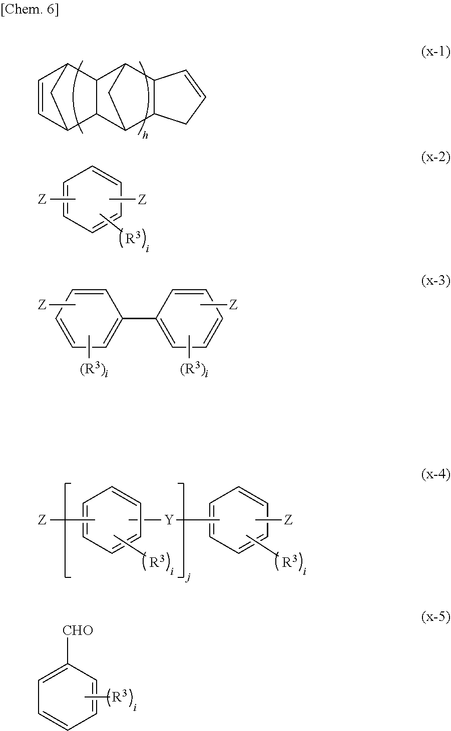

wherein h represents 0 or 1; R³'s each independently represent any one of an aliphatic hydrocarbon group, an alkoxy group, a halogen atom, an aryl group, and an aralkyl group; i represents 0 or an integer of 1 to 4; Z represents any one of a vinyl group, a halomethyl group, a hydroxymethyl group, and an alkyloxymethyl group; Y represents any one of an alkylene group having 1 to 4 carbon atoms, an oxygen atom, a sulfur atom, and a carbonyl group; and j represents an integer of 1 to 4,

under acid catalyst conditions and under the temperature conditions of about 80° C. to 180° C.

R³'s in structural formulas (x-1) to (x-5) described above each independently represent any one of an aliphatic hydrocarbon group, an alkoxy group, a halogen atom, an aryl group, and an aralkyl group, and these have the same meanings as the substituents for R² in structural formulas (X-1) to (X-5).

Z in structural formulas (x-1) to (x-5) is not particularly limited as long as the substituent is a functional group capable of forming a bond with the aromatic ring of the aromatic hydroxy compound; however, specific examples include a vinyl group, a halomethyl group, a hydroxymethyl group, and an alkyloxymethyl group.

Examples of the acid catalyst include para-toluenesulfonic acid, dimethylsulfuric acid, diethylsulfuric acid, sulfuric acid, hydrochloric acid, and oxalic acid. These may be respectively used singly, or two or more kinds thereof may be used in combination. Regarding the amount of addition of the acid catalyst, it is preferable to use the acid catalyst in an amount in the range of 0.01% to 10% by mass based on the amount of the naphthol compound (b).

The reaction proportions of the aromatic hydroxy compound and the compound (x) may vary depending on the designed value of n in structural formula (2); however, for example, it is preferable to use the aromatic hydroxy compound in an amount in the range of 2 to 10 mol with respect to 1 mol of the compound (x).

The reaction may be carried out in an organic solvent as necessary, and examples of the organic solvent include ketone solvents such as acetone, methyl ethyl ketone, and cyclohexanone; acetic acid ester solvents such as ethyl acetate, butyl acetate, cellosolve acetate, propylene glycol monomethyl ether acetate, and carbitol acetate; carbitol solvents such as cellosolve and butyl carbitol; aromatic hydrocarbon solvents such as toluene and xylene; dimethylformamide, dimethylacetamide, and N-methylpyrrolidone. These may be respectively used singly, or may be used as mixed solvents of two or more kinds thereof.

After completion of the reaction, an excess amount of the aromatic hydroxy compound may be distilled off or the like, if desired. Furthermore, after the reaction mixture is subjected to a neutralization treatment, the component represented by structural formula (2) may be purified from the reaction product by performing washing with water, reprecipitation, or the like.

It is preferable that the hydroxyl group equivalent of the compound represented by structural formula (2) is in an amount in the range of 140 to 300 g/equivalent.

Regarding the aromatic polycarboxylic acid or an acid halide thereof (b3), the specific structure is not particularly limited as long as the compound is an aromatic compound capable of forming an ester bond by reacting with the compound (b1) having one phenolic hydroxyl group and the compound (b2) having two or more phenolic hydroxyl groups, and any compound may be used. Specific examples include benzenedicarboxylic acids such as isophthalic acid and terephthalic acid; benzenetricarboxylic acids such as trimellitic acid; naphthalenedicarboxylic acids such as naphthalene-1,4-dicarboxylic acid, naphthalene-2,3-dicarboxylic acid, naphthalene-2,6-dicarboxylic acid, and naphthalene-2,7-dicarboxylic acid; acid halides of these; and compounds substituted with the above-mentioned aliphatic hydrocarbon group, alkoxy group, halogen atom, and the like on these aromatic nuclei. Examples of the acid halide include an acid chloride, an acid bromide, an acid fluoride, and an acid iodide. These may be respectively used singly, or two or more kinds may be used in combination. Among them, from the viewpoint of obtaining an active ester resin (B) having high reaction activity and excellent curability, a benzenedicarboxylic acid such as isophthalic acid or terephthalic acid, or an acid halide thereof is preferred.

The reaction between the compound (b1) having one phenolic hydroxyl group, the compound (b2) having two or more phenolic hydroxyl groups, and the aromatic polycarboxylic acid or an acid halide thereof (b3) can be carried out by, for example, a method of heating and stirring the compounds under the temperature conditions of about 40° C. to 65° C. in the presence of an alkali catalyst. The reaction may be carried out in an organic solvent, as necessary. Furthermore, after completion of the reaction, the reaction product may be purified by washing with water, reprecipitation, or the like, if desired.

Examples of the alkali catalyst include sodium hydroxide, potassium hydroxide, triethylamine, and pyridine. These may be respectively used singly, or two or more kinds thereof may be used in combination. Furthermore, the alkali catalyst may also be used as an aqueous solution at about 3.0% to 30%. Above all, sodium hydroxide or potassium hydroxide, both of which has high catalytic activity, is preferred.

Examples of the organic solvent include ketone solvents such as acetone, methyl ethyl ketone, and cyclohexanone; acetic acid ester solvents such as ethyl acetate, butyl acetate, cellosolve acetate, propylene glycol monomethyl ether acetate, and carbitol acetate; carbitol solvents such as cellosolve and butyl carbitol; aromatic hydrocarbon solvents such as toluene and xylene; dimethylformamide, dimethylacetamide, and N-methylpyrrolidone. These may be respectively used singly, or may be used as mixed solvents of two or more kinds thereof.

The reaction proportions of the compound (b1) having one phenolic hydroxyl group, the compound (b2) having two or more phenolic hydroxyl groups, and the aromatic polycarboxylic acid or an acid halide thereof (b3) can be varied as appropriate according to the desired molecular design. In particular, to make the active ester resin (B) highly-soluble in solvents and easy to be used in various applications, the ratio between the number of moles of hydroxyl groups (b1_{OH}) in the compound (b1) having one phenolic hydroxyl group and the number of moles of hydroxyl groups (b2_{OH}) in the compound (b2) having two or more phenolic hydroxyl groups, [(b1_{OH})/(b2_{OH})], is preferably 10/90 to 80/20, and more preferably 30/70 to 70/30. Furthermore, the total of the number of moles of hydroxyl groups in the compound having one phenolic hydroxyl group (b1) and the number of moles of hydroxyl groups in the compound (b2) having two or more phenolic hydroxyl groups is preferably 0.95 to 1.05 moles based on 1 mole of the total amount of carboxyl groups or acid halide groups in the aromatic polycarboxylic acid or an acid halide thereof (b3).

The active ester resin composition of the invention may be produced by a method of mixing the active ester compound (A) and the active ester resin (B), which have been separately synthesized by the methods described above, or may be produced by a method of simultaneously synthesizing the active ester compound (A) and the active ester resin (B). Specifically, the compound (b1) having one phenolic hydroxyl group, which is used as a raw material for the reaction to form the active ester resin (B) may be the same as the naphthol compound (a1) used as a raw material for the reaction to form the active ester compound (A). In this case, the active ester compound (A) and the active ester resin (B) can be synthesized simultaneously by appropriately adjusting the reaction proportions of the naphthol compound (a1), the compound (b2) having two or more phenolic hydroxyl groups, and the aromatic polycarboxylic acid or an acid halide (b3).

In a case in which the active ester compound (A) and the active ester resin (B) are synthesized simultaneously, in order to adjust the content of the active ester compound (A) with respect to the total amount of the active ester compound (A) and the active ester resin (B) to be 40% or more, it is preferable that the reaction proportions of the naphthol compound (a1), the compound (b2) having two or more phenolic hydroxyl groups, and the aromatic polycarboxylic acid or an acid halide thereof (b3) are as follows. First, the ratio between the number of moles of hydroxyl groups (a1_{OH}) in the naphthol compound (a1) and the number of moles of hydroxyl groups (b2_{OH}) in the compound (b2) having two or more phenolic hydroxyl groups, [(a1_{OH})/(b2_{OH})], is preferably 10/90 to 99/1, and more preferably 60/40 to 98/2. Furthermore, the total of the number of moles of hydroxyl groups in the naphthol compound (a1) and the number of moles of hydroxyl groups in the compound (b2) having two or more phenolic hydroxyl groups is preferably 0.95 to 1.05 moles based on 1 mole of the total amount of carboxyl groups or acid halide groups in the aromatic polycarboxylic acid or an acid halide thereof (b3).

From the viewpoint of obtaining an active ester resin having low cure shrinkage and also having excellent curability, the functional group equivalent of the active ester resin composition of the invention is preferably in the range of 200 to 360 g/equivalent. Meanwhile, the functional groups in the active ester resin composition according to the invention refer to the ester bond moiety and the phenolic hydroxyl group in the active ester resin composition. Furthermore, the functional group equivalent of the active ester resin composition is a value calculated from the feed amounts of the reaction raw materials.

Regarding the melt viscosity of the active ester resin composition of the invention, it is preferable that the value at 150° C. measured with an ICI viscometer according to ASTM D4287 is in the range of 0.1 to 50 dPa·s, and more preferably in the range of 0.1 to 5 dPa·s.

The curable resin composition of the invention includes the active ester resin composition and a curing agent. The curing agent may be any compound capable of reacting with the active ester resin composition of the invention, and various compounds can be utilized without any particular limitations. Regarding an example of the curing agent, for example, an epoxy resin may be mentioned.

Examples of the epoxy resin include a phenol novolac type epoxy resin, a cresol novolac type epoxy resin, a naphthol novolac type epoxy resin, a bisphenol novolac type epoxy resin, a biphenol novolac type epoxy resin, a bisphenol type epoxy resin, a biphenyl type epoxy resin, a triphenolmethane type epoxy resin, a tetraphenolethane type epoxy resin, a dicyclopentadiene phenol addition reaction type epoxy resin, a phenol aralkyl type epoxy resin, and a naphthol aralkyl type epoxy resin.

In regard to the curable composition of the invention, the mixing proportions of the active ester resin composition and the curing agent are not particularly limited and can be adjusted as appropriate according to the desired performance of the cured product, and the like. As an example of mixing in the case of using an epoxy resin as the curing agent, it is preferable that the mixing proportion of the total amount of functional groups in the active ester resin composition with respect to 1 mol of the total amount of epoxy groups in the curable composition is a proportion of 0.7 to 1.5 mol.

The curable composition of the invention may further include other resin components. Examples of the other resin components include amine compounds such as diaminodiphenylmethane, diethylenetriamine, triethylenetetramine, diaminodiphenylsulfone, isophoronediamine, imidazole, a BF₃-amine complex, and a guanidine derivative; amide compounds such as dicyandiamide, and a polyamide resin synthesized from a linolenic acid dimer and ethylenediamine; acid anhydrides such as phthalic anhydride, trimellitic anhydride, pyromellitic anhydride, maleic anhydride, tetrahydrophthalic anhydride, methyltetrahydrophthalic anhydride, methylnadic anhydride, hexahydrophthalic anhydride, and methylhexahydrophthalic anhydride; phenolic resins such as a phenol novolac resin, a cresol novolac resin, a naphthol novolac resin, a bisphenol novolac resin, a biphenyl novolac resin, a dicyclopentadiene phenol addition type resin, a phenol aralkyl resin, a naphthol aralkyl resin, a triphenolmethane type resin, a tetraphenolethane type resin, and an aminotriazine-modified phenolic resin; cyanic acid ester resins; bismaleimide resins, benzoxazine resins; styrene-maleic anhydride resins; allyl group-containing resins represented by diallyl bisphenol or triallyl isocyanurate; and polyphosphoric acid esters or phosphoric acid ester-carbonate copolymers. These may be respectively used singly, or two or more kinds thereof may be used in combination.

The mixing proportion of these other resin components is not particularly limited and can be adjusted as appropriate according to the desired performance of the cured product, and the like. As an example of the mixing proportion, it is preferable to use the other resin components at a proportion in the range of 1% to 50% by mass in the curable composition of the invention.

The curable resin composition of the invention may include various additives such as a curing accelerator, a flame retardant, an inorganic filler material, a silane coupling agent, a mold release agent, a pigment, and an emulsifier, as necessary.

Examples of the curing accelerator include a phosphorus-based compound, a tertiary amine, an imidazole compound, a pyridine compound, an organic acid metal salt, a Lewis acid, and an amine complex salt. Among them, from the viewpoint of having excellent curability, heat resistance, electrical characteristics, moisture-resistant reliability, and the like, the phosphorus-based compound is preferably triphenylphosphine, the tertiary amine is preferably 1,8-diazabicyclo[5.4.0]-undecene (DBU), the imidazole compound is preferably 2-ethyl-4-methylimidazole, and the pyridine compound is preferably 4-dimethylaminopyridine.

Examples of the flame retardant include inorganic phosphorus compounds including red phosphorus, ammonium phosphates such as monoammonium phosphate, diammonium phosphate, triammonium phosphate, and ammoniumpolyphosphate, and phosphoric acid amide; organic phosphorus compounds including a phosphoric acid ester compound, a phosphonic acid compound, a phosphinic compound, a phosphine oxide compound, a phosphorane compound, an organic nitrogen-containing phosphorus compound, cyclic organic phosphorus compounds such as 9,10-dihydro-9-oxa-10-phosphaphenanthrene-10-oxide, 10-(2,5-dihydrooxyphenyl)-10H-9-oxa-10-phosphaphenanthrene-10-oxide, and 10-(2,7-dihydrooxynaphthyl)-10H-9-oxa-10-phosphaphenanthrene-10-oxide, and derivatives obtained by reacting those compounds with compounds such as an epoxy resin and a phenolic resin; nitrogen-based flame retardants such as a triazine compound, a cyanuric acid compound, an isocyanuric acid compound, and phenothiazine; silicone-based flame retardants such as a silicone oil, a silicone rubber, and a silicone resin; and inorganic flame retardants such as a metal hydroxide, a metal oxide, a metal carbonate compound, a powdered metal, a boron compound, and a low-melting point glass. In the case of using these flame retardants, the content is preferably in the range of 0.1% to 20% by mass in the curable resin composition.

The inorganic filler material is incorporated, for example, in a case in which the curable resin composition of the invention is used for semiconductor encapsulating material applications. Examples of the organic filler material include fused silica, crystalline silica, alumina, silicon nitride, and aluminum hydroxide. Among them, since an inorganic filler material can be incorporated in a larger quantity, the fused silica is preferred. Regarding the fused silica, any of a crushed form and a spherical form can be used; however, in order to increase the amount of incorporation of fused silica and to suppress an increase in the melt viscosity of the curable composition, it is preferable to use mainly a spherical-shaped fused silica. Furthermore, in order to increase the amount of incorporation of spherical silica, it is preferable that the particle size distribution of the spherical silica is adjusted appropriately. Regarding the filling ratio, it is preferable to incorporate the spherical silica in an amount in the range of 0.5 parts to 95 parts by mass in 100 parts by mass of the curable resin composition.

In addition to this, in a case in which the curable resin composition of the invention is used for use applications such as an electroconductive paste, electroconductive fillers such as powdered silver and powdered copper can be used.

As described above, the active ester resin composition of the invention has excellent performance such as low shrinkage upon curing and a low elastic modulus under high temperature conditions in the cured product. In addition to this, the active ester resin also has sufficiently high general requisite performance that is required from a resin material, such as solubility in general-purpose organic solvents, curability with an epoxy resin, and heat resistance of the cured product. Thus, the active ester resin composition can be widely utilized for electronic material applications such as a printed wiring board, a semiconductor encapsulating material, and a resist material, as well as for applications such as a coating material, an adhesive, and a molded article.

In the case of using the curable resin composition of the invention for a semiconductor encapsulating material application, generally, it is preferable to incorporate an inorganic filler material into the resin composition. The semiconductor encapsulating material can be produced by, for example, mixing a blend using an extruder, a kneader, a roll, or the like. The method of molding a semiconductor package using the semiconductor encapsulating material thus obtained may be, for example, a method of molding the semiconductor encapsulating material using a cast or transfer molding machine, an injection molding machine, or the like, and heating the resultant under the temperature conditions of 50° C. to 200° C. for 2 to 10 hours. A semiconductor device as a molded article can be obtained by such a method.

In the case of using the curable resin composition of the invention for a printed wiring board application or a build-up adhesive film application, generally, it is preferable to use the curable resin composition after incorporating an organic solvent into the resin composition and diluting the composition. Examples of the organic solvent include methyl ethyl ketone, acetone, dimethylformamide, methyl isobutyl ketone, methoxypropanol, cyclohexanone, methyl cellosolve, ethyl diglycol acetate, and propylene glycol monomethyl ether acetate. The type or the amount of incorporation of the organic solvent can be appropriately adjusted according to the use environment of the curable resin composition; however, for example, for a printed wiring board application, the organic solvent is preferably a polar solvent having a boiling point of 160° C. or lower, such as methyl ethyl ketone, acetone, or dimethylformamide. It is preferable to use the solvent at a proportion such that the non-volatile fraction is 40% to 80% by mass. For a build-up adhesive film application, it is preferable to use a ketone solvent such as acetone, methyl ethyl ketone, or cyclohexanone; an acetic acid ester solvent such as ethyl acetate, butyl acetate, cellosolve acetate, propylene glycol monomethyl ether acetate, or carbitol acetate; a carbitol solvent such as cellosolve or butyl carbitol; an aromatic hydrocarbon solvent such as toluene or xylene; dimethylformamide, dimethylacetamide, N-methylpyrrolidone, or the like. It is preferable to use the organic solvent at a proportion such that the non-volatile fraction is 30% to 60% by mass.

Furthermore, the method for producing a printed wiring board using the curable resin composition of the invention may be, for example, a method of impregnating a reinforcing base material with the curable composition, curing the composition to obtain a prepreg, laminating this with a copper foil, and heating and compressing the laminate. Examples of the reinforcing base material include paper, a glass fabric, a glass nonwoven fabric, an aramid paper, an aramid fabric, a glass mat, and a glass woven roving. The amount of impregnation of the curable resin composition is not particularly limited; however, usually, it is preferable to produce the prepreg such that the resin fraction in the prepreg is 20% to 60% by mass.

### EXAMPLES

Next, the present invention will be specifically described by way of Examples and Comparative Examples. The description of the units “parts” and “percent (%)” in the Examples is on a mass basis unless particularly stated otherwise. Meanwhile, the measurement conditions for melt viscosity and GPC in the present Examples were as follows.

Method for Measuring Melt Viscosity

The melt viscosity at 150° C. was measured using an ICI viscometer according to ASTM D4287.

Measurement Conditions for GPC

Measuring apparatus: “HLC-8320 GPC” manufactured by Tosoh Corporation
Column: Guide column “HXL-L” manufactured by Tosoh Corporation
“TSK-GEL G2000HXL” manufactured by Tosoh Corporation
“TSK-GEL G2000HXL” manufactured by Tosoh Corporation
“TSK-GEL G3000HXL” manufactured by Tosoh Corporation
“TSK-GEL G4000HXL” manufactured by Tosoh Corporation
   Detector: RI (differential refractometer)
   Data processing: “GPC Workstation EcoSEC-WorkStation” manufactured by Tosoh Corporation
   Measurement conditions: Column temperature 40° C.
Developing solvent tetrahydrofuran
Flow rate 1.0 ml/min
   Standard: The following monodisperse polystyrenes having known molecular weights were used according to the measurement manual of “GPC Workstation EcoSEC-WorkStation”.

(Polystyrenes Used)
“A-500” manufactured by Tosoh Corporation
“A-1000” manufactured by Tosoh Corporation
“A-2500” manufactured by Tosoh Corporation
“A-5000” manufactured by Tosoh Corporation
“F-1” manufactured by Tosoh Corporation
“F-2” manufactured by Tosoh Corporation
“F-4” manufactured by Tosoh Corporation
“F-10” manufactured by Tosoh Corporation
“F-20” manufactured by Tosoh Corporation
“F-40” manufactured by Tosoh Corporation
“F-80” manufactured by Tosoh Corporation
“F-128” manufactured by Tosoh Corporation
   Sample: A tetrahydrofuran solution having a concentration of 1.0% by mass in terms of the resin solid content was filtered through a microfilter (50 μl) and used.

### Example 1: Production of Active Ester Resin Composition (1)

Into a flask equipped with a thermometer, a dropping funnel, a cooling tube, a fractionation column, and a stirrer, 202.0 g of isophthalic acid chloride and 1,250 g of toluene were introduced, and the mixture was dissolved while the interior of the system was purged with nitrogen under reduced pressure. Next, 279.5 g of 1-naphthol and 9.7 g of an addition reaction product of dicyclopentadiene and phenol (hydroxyl group equivalent 165 g/equivalent) were introduced into the flask, and the mixture was dissolved while the interior of the system was purged with nitrogen under reduced pressure. 0.63 g of tetrabutylammonium bromide was added thereto, and while the flask was subjected to nitrogen gas purge, the interior of the reaction system was controlled to be 60° C. or lower. 400 g of a 20% aqueous solution of sodium hydroxide was added dropwise thereto over 3 hours. After completion of the dropwise addition, the mixture was continuously stirred for one hour without changing any conditions and was thereby caused to react. After completion of the reaction, the reaction mixture was left to stand and partitioned, and an aqueous layer was removed. Water was added to the remaining organic layer, and the mixture was stirred and mixed for about 15 minutes. Then, the mixture was left to stand and partitioned, and an aqueous layer was removed. This operation was repeated until the pH of the aqueous layer reached 7, and then moisture and toluene were removed by decantation dehydration. Thus, an active ester resin composition (1) was obtained. The melt viscosity of the active ester resin composition (1) was 0.6 dPa·s. Furthermore, the content of the active ester compound (A) in the active ester resin composition (1) calculated from a GPC chart was 94.2%.

### Example 2: Production of Active Ester Resin Composition (2)

Into a flask equipped with a thermometer, a dropping funnel, a cooling tube, a fractionation column, and a stirrer, 202.0 g of isophthalic acid chloride and 1,270 g of toluene were introduced, and the mixture was dissolved while the interior of the system was purged with nitrogen under reduced pressure. Next, 246.9 g of 1-naphthol and 47.1 g of an addition reaction product of dicyclopentadiene and phenol (hydroxyl group equivalent 165 g/equivalent) were introduced into the flask, and the mixture was dissolved while the interior of the system was purged with nitrogen under reduced pressure. 0.63 g of tetrabutylammonium bromide was added thereto, and while the flask was subjected to nitrogen gas purge, the interior of the system was controlled to be 60° C. or lower. 400 g of a 20% aqueous solution of sodium hydroxide was added dropwise thereto over 3 hours. After completion of the dropwise addition, the mixture was continuously stirred for one hour without changing any conditions and thereby was caused to react. After completion of the reaction, the reaction mixture was left to stand and partitioned, and an aqueous layer was removed. Water was added to the remaining organic layer, and the organic layer was stirred and mixed for about 15 minutes. Subsequently, the mixture was left to stand and partitioned, and an aqueous layer was removed. This operation was repeated until the pH of the aqueous layer reached 7, and then moisture and toluene were removed by decantation dehydration. Thus, an active ester resin composition (2) was obtained. The melt viscosity of the active ester resin composition (2) was 2.5 dPa·s. Furthermore, the content of the active ester compound (A) in the active ester resin composition (2) calculated from a GPC chart was 73.4%.

### Example 3: Production of Active Ester Resin Composition (3)

Into a flask equipped with a thermometer, a dropping funnel, a cooling tube, a fractionation column, and a stirrer, 202.0 g of isophthalic acid chloride and 1,300 g of toluene were introduced, and the mixture was dissolved while the interior of the system was purged with nitrogen under reduced pressure. Next, 192.0 g of 1-naphthol and 110.0 g of an addition reaction product of dicyclopentadiene and phenol (hydroxyl group equivalent 165 g/equivalent) were introduced into the flask, and the mixture was dissolved while the interior of the system was purged with nitrogen under reduced pressure. 0.65 g of tetrabutylammonium bromide was added thereto, and while the flask was subjected to nitrogen gas purge, the interior of the system was controlled to be 60° C. or lower. 400 g of a 20% aqueous solution of sodium hydroxide was added dropwise thereto over 3 hours. After completion of the dropwise addition, the mixture was continuously stirred for one hour without changing any conditions and thereby was caused to react. After completion of the reaction, the reaction mixture was left to stand and partitioned, and an aqueous layer was removed. Water was added to the remaining organic layer, and the organic layer was stirred and mixed for about 15 minutes. Subsequently, the mixture was left to stand and partitioned, and an aqueous layer was removed. This operation was repeated until the pH of the aqueous layer reached 7, and then moisture and toluene were removed by decantation dehydration. Thus, an active ester resin composition (3) was obtained. The melt viscosity of the active ester resin composition (3) was 33.0 dPa·s. Furthermore, the content of the active ester compound (A) in the active ester resin composition (3) calculated from a GPC chart was 43.4%.

### Example 4: Production of Active Ester Resin Composition (4)

Into a flask equipped with a thermometer, a dropping funnel, a cooling tube, a fractionation column, and a stirrer, 576 g of 1-naphthol, 81 g of a 37 mass % aqueous solution of formaldehyde, and 670 g of distilled water were introduced, and the mixture was stirred at room temperature while nitrogen was blown into the flask. Subsequently, the temperature was raised to 95° C., and the mixture was stirred for 2 hours. After completion of the reaction, water and unreacted monomers were removed under heated and reduced pressure conditions, and a naphthol novolac resin having a hydroxyl group equivalent of 151 g/equivalent was obtained.

Into a flask equipped with a thermometer, a dropping funnel, a cooling tube, a fractionation column, and a stirrer, 202.0 g of isophthalic acid chloride and 1,250 g of toluene were introduced, and the mixture was dissolved while the interior of the system was purged with nitrogen under reduced pressure. Next, 279.5 g of 1-naphthol and 8.9 g of the naphthol novolac resin obtained as described above were introduced into the flask, and the mixture was dissolved while the interior of the system was purged with nitrogen under reduced pressure. 0.63 g of tetrabutylammonium bromide was added thereto, and while the flask was subjected to nitrogen gas purge, the interior of the system was controlled to be 60° C. or lower. 400 g of a 20% aqueous solution of sodium hydroxide was added dropwise thereto over 3 hours. After completion of the dropwise addition, the mixture was continuously stirred for one hour without changing the conditions and was thereby caused to react. After completion of the reaction, the reaction mixture was left to stand and partitioned, and an aqueous layer was removed. Water was added to the remaining organic layer, and the mixture was stirred and mixed for about 15 minutes. Subsequently, the mixture was left to stand and partitioned, and an aqueous layer was removed. This operation was repeated until the pH of the aqueous layer reached 7, and then moisture and toluene were removed by decantation hydration. Thus, an active ester resin composition (4) was obtained. The melt viscosity of the active ester resin composition (4) was 0.9 dPa·s. Furthermore, the content of the active ester compound (A) in the active ester resin composition (4) calculated from a GPC chart was 94.0%.

### Example 5: Production of Active Ester Resin Composition (5)

Into a flask equipped with a thermometer, a dropping funnel, a cooling tube, a fractionation column, and a stirrer, 576 g of 1-naphthol, 138 g of benzenedimethanol, 1,200 g of toluene, and 2 g of para-toluenesulfonic acid monohydrate were introduced, and the mixture was stirred at room temperature while nitrogen was blown into the flask. Subsequently, the temperature was raised to 120° C., and while water thus produced was distilled off out of the system, the mixture was stirred for 4 hours. After completion of the reaction, 2 g of a 20% aqueous solution of sodium hydroxide was added to the flask to neutralize the reaction mixture, and moisture, toluene, and unreacted monomers were removed under reduced pressure conditions. Thus, a naphthol resin having a hydroxyl group equivalent of 187 g/equivalent was obtained.

Into a flask equipped with a thermometer, a dropping funnel, a cooling tube, a fractionation column, and a stirrer, 202.0 g of isophthalic acid chloride and 1,250 g of toluene were introduced, and the mixture was dissolved while the interior of the system was purged with nitrogen under reduced pressure. Next, 279.5 g of 1-naphthol and 11.0 g of the naphthol resin obtained as described above were introduced into the flask, and the mixture was dissolved while the interior of the system was purged with nitrogen under reduced pressure. 0.63 g of tetrabutylammonium bromide was added thereto, and while the flask was subjected to nitrogen gas purge, the interior of the system was controlled to be 60° C. or lower. 400 g of a 20% aqueous solution of sodium hydroxide was added dropwise thereto over 3 hours. After completion of the dropwise addition, the mixture was continuously stirred for one hour without changing the conditions and was thereby caused to react. After completion of the reaction, the reaction mixture was left to stand and partitioned, and an aqueous layer was removed. Water was added to the remaining organic layer, and the mixture was stirred and mixed for about 15 minutes. Subsequently, the mixture was left to stand and partitioned, and an aqueous layer was removed. This operation was repeated until the pH of the aqueous layer reached 7, and then moisture and toluene were removed by decantation dehydration. Thus, an active ester resin (5) was obtained. The melt viscosity of the active ester resin composition (5) was 0.9 dPa·s. Furthermore, the content of the active ester compound (A) in the active ester resin composition (5) calculated from a GPC chart was 94.6%.

### Examples 6 to 10 and Comparative Example 1

Various components were mixed at the proportions indicated in the following Table 1, and thus a curable resin composition (1) was obtained. For the curable resin composition (1) thus obtained, the cure shrinkage and the elastic modulus under high temperature conditions of the cured product were measured by the following methods. The results are presented in Table 1.

Measurement of Cure Shrinkage

The curable resin composition (1) was injection-molded using a transfer molding machine (“KTS-15-1.5C” manufactured by Kohtaki Precision Machine Co., Ltd.) under the conditions of a mold temperature of 154° C., a molding pressure of 9.8 MPa, and a curing time of 600 seconds, and a molded product having a length of 110 mm, a width of 12.7 mm, and a thickness of 1.6 mm was obtained. Next, the molded product thus obtained was cured for 5 hours at 175° C., and then the molded product was left to stand for 24 hours or longer at room temperature (25° C.). This was used as a specimen. The dimension in the longitudinal direction of the specimen at room temperature, and the dimension in the longitudinal direction of the mold at 154° C. were respectively measured, and the cure shrinkage was calculated by the following Formula.

Cure shrinkage (%)={(Dimension in longitudinal direction of mold at 154° C.)−(dimension in longitudinal direction of specimen at room temperature)}/(dimension in longitudinal direction of mold at 154° C.)×100(%)

TABLE 1

| | | Example | Example | Example | Example | Example | Comparative |
|---|---|---|---|---|---|---|---|
| | | 6 | 7 | 8 | 9 | 10 | Example 1 |
| Active ester resin composition (1) | [parts by mass] | 50.8 | | | | | |
| Active ester resin composition (2) | [parts by mass] | | 51.2 | | | | |
| Active ester resin composition (3) | [parts by mass] | | | 51.7 | | | |
| Active ester resin composition (4) | [parts by mass] | | | | 50.9 | | |
| Active ester resin composition (5) | [parts by mass] | | | | | 51.1 | |
| Phenol novolac resin (*1) | [parts by mass] | | | | | | 66.0 |
| Epoxy resin (*2) | [parts by mass] | 49.2 | 48.8 | 48.3 | 49.1 | 48.9 | 34.0 |
| Dimethylaminopyridine | [parts by mass] | 1.0 | 1.0 | 1.0 | 1.0 | 1.0 | 1.0 |
| Fused silica | [parts by mass] | 100.0 | 100.0 | 100.0 | 100.0 | 100.0 | 100.0 |
| Silane coupling agent | [parts by mass] | 0.5 | 0.5 | 0.5 | 0.5 | 0.5 | 0.5 |
| Carnauba wax | [parts by mass] | 0.7 | 0.7 | 0.7 | 0.7 | 0.7 | 0.7 |

| | | | | | | |
|---|---|---|---|---|---|---|
| Cure shrinkage [%] | 0.78 | 0.75 | 0.89 | 0.64 | 0.71 | 0.94 |

Phenol novolac resin (*1): “TD-2131” manufactured by DIC Corporation, hydroxyl group equivalent 104 g/equivalent
Epoxy resin (*2): Cresol novolac type epoxy resin (“N-655-EXP-S” manufactured by DIC Corporation, epoxy equivalent 202 g/equivalent)

### Examples 11 to 15 and Comparative Example 2

Various components were mixed at the proportions indicated in the following Table 2, and a curable resin composition (2) was obtained. For the curable resin composition (2) thus obtained, the elastic modulus under high temperature conditions of the cured product was measured by the following method. The results are presented in Table 2.

Measurement of Elastic Modulus Under High Temperature Conditions of Cured Product

The curable resin composition (2) was poured into a molding flask and was molded at a temperature of 175° C. for 10 minutes using a pressing machine. The molded product was taken out from the molding flask and was cured for 5 hours at a temperature of 175° C. The molded product obtained after curing was cut out into a size of 5 mm×54 mm×2.4 mm, and this was used as a specimen.

The storage modulus at 260° C. of the specimen was measured using a viscoelasticity measuring apparatus (“Solid Viscoelasticity Measuring Apparatus RSAII” manufactured by Rheometrics, Inc.) under the conditions of a rectangular tension method, a frequency of 1 Hz, and a temperature increase of 3° C./min.

TABLE 2

| | | Example | Example | Example | Example | Example | Comparative |
|---|---|---|---|---|---|---|---|
| | | 11 | 12 | 13 | 14 | 15 | Example 2 |
| Active ester resin composition (1) | [parts by mass] | 50.8 | | | | | |
| Active ester resin composition (2) | [parts by mass] | | 51.2 | | | | |
| Active ester resin composition (3) | [parts by mass] | | | 51.7 | | | |
| Active ester resin composition (4) | [parts by mass] | | | | 50.9 | | |
| Active ester resin composition (5) | [parts by mass] | | | | | 51.1 | |
| Phenol novolac resin (*1) | [parts by mass] | | | | | | 66.0 |
| Epoxy resin (*2) | [parts by mass] | 49.2 | 48.8 | 48.3 | 49.1 | 48.9 | 34.0 |
| Dimethylaminopyridine | [parts by mass] | 1.0 | 1.0 | 1.0 | 1.0 | 1.0 | 1.0 |

| | | | | | | |
|---|---|---|---|---|---|---|
| Storage modulus at 260° C. [MPa] | 11 | 11 | 17 | 15 | 11 | 50 |

Phenol novolac resin (*1): “TD-2131” manufactured by DIC Corporation, hydroxyl group equivalent 104 g/equivalent
Epoxy resin (*2): Cresol novolac type epoxy resin (“N-655-EXP-S” manufactured by DIC Corporation, epoxy equivalent 202 g/equivalent)

1. An active ester resin composition comprising:
an active ester compound (A) that is an esterification product of a naphthol compound (a1) and an aromatic polycarboxylic acid or an acid halide thereof (a2); and
an active ester resin (B) comprising a product of reaction of essential raw materials including a compound (b1) having one phenolic hydroxyl group, a compound (b2) having two or more phenolic hydroxyl groups, and an aromatic polycarboxylic acid or an acid halide thereof (b3),
wherein the content of the active ester compound (A) is in the range of 50% to 99% based on the total amount of the active ester compound (A) and the active ester resin (B).

2. The active ester resin composition according to claim 1, wherein the active ester compound (A) has a molecular structure represented by the following structural formula (1): 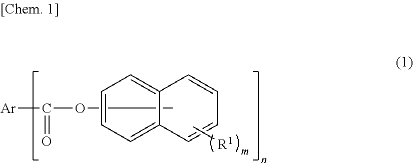
wherein Ar represents any one of a benzene ring, a naphthalene ring, and an anthracene ring; R¹'s each independently represent any one of an aliphatic hydrocarbon group, an alkoxy group, a halogen atom, an aryl group, and an aralkyl group; m represents 0 or an integer from 1 to 4; and n represents an integer of 2 or 3.

3. A curable resin composition comprising: the active ester resin composition according to 1; and a curing agent.

4. A cured product comprising a product obtained by curing the curable resin composition according to claim 3.

5. A semiconductor encapsulating material comprising the curable resin composition according to claim 3.

6. A printed wiring board comprising a product produced using the curable resin composition according to claim 3.

7. The active ester resin composition according to claim 1, wherein the content of the active ester compound (A) is in the range of 65% to 99%.

8. The active ester resin composition according to claim 1, wherein the compound (b2) having two or more phenolic hydroxyl groups is a compound having a molecular structure represented by the following structural formula (2): 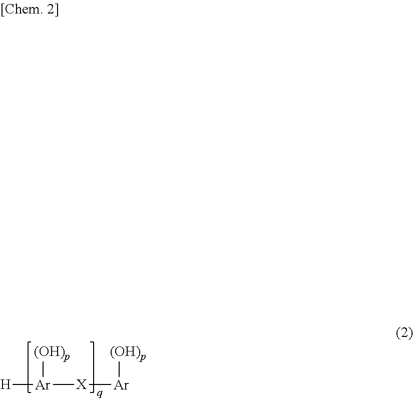
wherein p represents 1 or 2; q represents an integer of 1 to 4; Ar represents an aromatic ring on which any one or more substituents may exist; and X represents a structural moiety represented by the following structural formula (X-1): 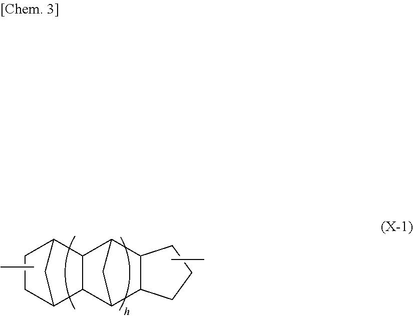
wherein h represents 0 or 1.

9. The active ester resin composition according to claim 1, wherein the compound (b2) having two or more phenolic hydroxyl groups is a novolac type phenolic resin produced by reaction of a phenolic hydroxyl group-containing compound and formaldehyde as raw materials.

10. The active ester resin composition according to claim 1, wherein the compound (b2) having two or more phenolic hydroxyl groups is a compound having a molecular structure represented by the following structural formula (2): 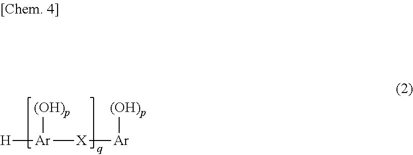
wherein p represents 1 or 2; q represents an integer from 1 to 4; Ar represents an aromatic ring on which any one or more substituents may exist; and X represents a structural moiety represented by any one of the following structural formulas (X-2) to (X-5): 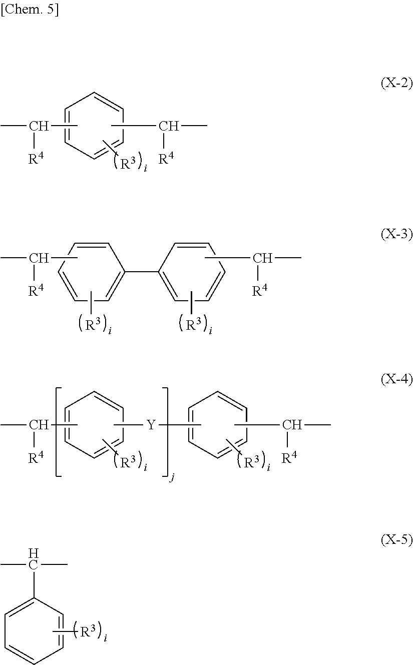
wherein R³'s each independently represent any one of an aliphatic hydrocarbon group, an alkoxy group, a halogen atom, an aryl group, and an aralkyl group; i represents 0 or an integer from 1 to 4; R⁴ represents a hydrogen atom or a methyl group; Y represents any one of an alkylene group having 1 to 4 carbon atoms, an oxygen atom, a sulfur atom, and a carbonyl group; and j represents an integer from 1 to 4.

11. A curable resin composition comprising: the active ester resin composition according to 2; and a curing agent.

12. A curable resin composition comprising: the active ester resin composition according to 7; and a curing agent.

13. A curable resin composition comprising: the active ester resin composition according to 8; and a curing agent.

14. A curable resin composition comprising: the active ester resin composition according to 9; and a curing agent.

15. A curable resin composition comprising: the active ester resin composition according to 10; and a curing agent.

16. A cured product comprising a product obtained by curing the curable resin composition according to claim 11.

17. A cured product comprising a product obtained by curing the curable resin composition according to claim 12.

18. A semiconductor encapsulating material comprising the curable resin composition according to claim 11.

19. A semiconductor encapsulating material comprising the curable resin composition according to claim 12.

20. A printed wiring board comprising a product produced using the curable resin composition according to claim 11.
